(19) United States
(12) Patent Application Publication
(10) Pub. No.: US 2025/0233044 A1
(43) Pub. Date: Jul. 17, 2025

(54) MEMORY DEVICE WITH ENHANCED THERMAL CONDUCTIVITY

(71) Applicant: Micron Technology, Inc., Boise, ID (US)

(72) Inventors: Eiichi Nakano, Boise, ID (US); Amy R. Griffin, Boise, ID (US); Derek Q. Nesbitt, Boise, ID (US)

(21) Appl. No.: 18/979,663

(22) Filed: Dec. 13, 2024

Related U.S. Application Data
(60) Provisional application No. 63/620,448, filed on Jan. 12, 2024.

(51) Int. Cl. H01L 23/373; H01L 23/498; H01L 25/18; H10B 80/00

(52) U.S. Cl. CPC H01L 23/3736; H01L 23/49827; H01L 25/18; H10B 80/00; H01L 23/49838; H01L 2225/06544

(57) ABSTRACT

Systems, apparatuses, and methods related to a memory device with enhanced thermal conductivity are described. Embodiments of the present technology can include thermal paths, such as material with a thermal conductivity value less than a threshold value, added into one or more layers in a memory device structure. The added material can provide a path for the thermal energy to dissipate from the memory device.

### CROSS-REFERENCE TO RELATED APPLICATION(S)

The present application claims priority to U.S. Provisional Patent Application No. 63/620,448, filed Jan. 12, 2024, the disclosure of which is incorporated herein by reference in its entirety.

### TECHNICAL FIELD

This disclosure relates generally to electronic devices, and more particularly, to memory devices having structures with enhanced thermal conductivity.

### BACKGROUND

An apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing circuit capacity, increasing operating speeds, increasing reliability, increasing data retention, among other metrics. However, attempts to meet the market demands, such as by increasing bandwidth capability, can often be limited by the thermal conductivity of the materials of the device.

### BRIEF DESCRIPTION OF THE DRAWINGS

FIG. 1 is a block diagram of an apparatus in accordance with an embodiment of the present technology.

FIG. 2 illustrates a cross-sectional view of the apparatus having a thermal path, in accordance with one or more embodiments of the present technology.

FIG. 3A illustrates a cross-sectional view of the formation of an isolation layer in a memory device structure, in accordance with one or more embodiments of the present technology.

FIG. 3B illustrates a cross-sectional view of the formation of local interconnects and wiring in a memory device structure, in accordance with one or more embodiments of the present technology.

FIG. 3C illustrates a cross-sectional view of the formation of a base dielectric layer of a memory device structure, in accordance with one or more embodiments of the present technology.

FIG. 4A illustrates a cross-sectional view of the formation of a cell structure in the base dielectric layer in a memory device structure, in accordance with one or more embodiments of the present technology.

FIG. 4B illustrates a cross-sectional view of the formation of an isolated area for a thermal path in a memory device structure, in accordance with one or more embodiments of the present technology.

FIG. 4C illustrates a cross-sectional view of the formation of a thermal path in a memory device structure, in accordance with one or more embodiments of the present technology.

FIG. 5A illustrates a cross-sectional view of the formation a thermal path from the base dielectric layer and connected to the isolation layer in a memory device structure, in accordance with one or more embodiments of the present technology.

FIG. 5B illustrates a cross-sectional view of the formation of a thermal path through the base dielectric layer and connected to the isolation layer in a memory device structure, in accordance with one or more embodiments of the present technology.

FIG. 5C illustrates a cross-sectional view of a thermal path in a memory device, in accordance with one or more embodiments of the present technology.

FIG. 6A illustrates a cross-sectional view of the formation of a via in a memory device structure, in accordance with one or more embodiments of the present technology.

FIG. 6B illustrates a cross-sectional view of the formation of a via in the end-of-line layer of a memory device structure, in accordance with one or more embodiments of the present technology.

FIG. 7 illustrates a cross-sectional view of thermal paths on memory devices connected to a logic circuit of an apparatus, in accordance with one or more embodiments of the present technology.

FIG. 8A is a flow diagram illustrating an example method of designing a thermal path for a memory device structure, in accordance with one or more embodiments of the present technology.

FIG. 8B is a flow diagram illustrating an example method of manufacturing a thermal path in one or more layers of a memory device structure, in accordance with one or more embodiments of the present technology.

FIG. 9 is a schematic view of a system that includes an apparatus in accordance with embodiments of the present technology.

### DETAILED DESCRIPTION

As described in greater detail below, the technology disclosed herein relates to an apparatus, such as for memory devices, memory systems, systems with memory devices, related methods, etc., with enhanced thermal conductivity. Memory devices, such as dynamic random-access memory (DRAM), include materials and structures configured to utilize electrical energy to store and access data. With the growth of high-powered computing, such as artificial intelligence, virtual reality, machine learning, etc., bandwidth requirements have increased for memory devices. However, the performance of conventional memory systems has been limited due to the thermal conductivity of the materials in memory devices.

Embodiments of the present technology can provide improvements in the thermal conductivity of a memory device by adding materials (e.g., Aluminum Oxide, Aluminum Nitride, etc.) in the memory device structure. The added material can be more thermally conductive than dielectric material used within the structure of the memory device. Additionally, the thermally conductive material can be added at targeted locations to provide a thermal path configured to transfer the thermal energy out of the memory device. For example, the thermally conductive material can be located at the same layer as and adjacent to memory cells. Further, the thermally conductive material can overlap each other across the layers (e.g., aligned along a vertical line/direction), thereby providing a vertically coupled thermal or heat dissipation path. The resulting vertical heat dissipation path can leverage the rising nature of thermal energy to increase the dissipation efficiency and, when implemented in stacked assemblies, provide a new dissipation path for devices located on the lower portions of the stack. Additionally, when implemented in circuits having repetitive patterns, such as in memory arrays, the locations for the thermally conductive material can also follow the repetitive patterns and increase the heat dissipation for the overall device/assembly.

Further in comparison to the conventional devices, the thermally conductive material can be added to regions that are occupied by dielectric material in conventional devices. Accordingly, the embodiments described herein can replace previous dielectric material (using, e.g., thermally-conductive electrical insulators, such as Aluminum Nitride) to provide heat dissipation paths within conventionally insulative structures.

In some embodiments, the thermally conductive material can be added during the front-end-of-line (FEOL) layer manufacturing phase. The FEOL layer can include the isolation layer that interconnects with a complementary metal-oxide semiconductor (CMOS) formation and local wiring. For forming or adding the thermally conductive material during the FEOL manufacturing phase, a base dielectric layer can be formed on the isolation layer. Next, a cell structure (e.g., individual memory cells) can be formed in the base dielectric layer. Adjacent to the cell structure, an isolated area for a thermal path can be formed in the base dielectric layer. The area of thermal path can be electrically isolated using the base dielectric layer from the area of peripheral circuitry and the areas of contact, vias, and/or TSVs, such as by preserving or forming vertical portions or walls surrounding the thermal path portions.

A thermal path can be formed in the dielectric layer at the area of thermal path by adding thermally conductive, electrically non-conductive material such as Aluminum Oxide, Aluminum Nitride, etc. The thermal path can be formed by a process of spin coating, which contains the thermally conductive material as a filler in the base dielectric layer. In some embodiments, the thermal path is formed by a combination of processes, such as physical vapor deposition (PVD), molybdenum (MO), or cut metal dielectric (CMD), to form a thermally conductive layer as a functional film and removed by a polishing process. The manufacturing process can be completed by implementing a back end-of-line (BEOL) process to form the wiring of the memory device.

As described in detail below, embodiments of the present technology can provide technical advantages over conventional technology by providing an extensive thermal path to improve device performance. For example, the cell area of a nominal memory device is ˜50% of the total device area. The cell materials have a relatively higher thermal conductivity than the dielectric films used in a semiconductor manufacturing process. The thermal path, which is made of material with higher thermal conductivity than the cell materials, creates a path for the thermal energy to exit the device. Moreover, the size, the shape, and the content of the thermally conductive material can be used to reduce mismatches in thermal conductivity across lateral directions/plane, thereby reducing potential warpage issues.

Embodiments of the present technology introduce a thermal path in the dielectric area for providing higher thermal conductivity while preserving the electrical integrity, by: 1) using material such as Aluminum Oxide, Aluminum Nitride, etc., to minimize electrical interaction with circuitry; 2) isolating the area of the via/contact/TSV, to eliminate the technical difficulty to form the via/contact/TSV structures in the material for the thermal path; and 3) using material such as Aluminum Oxide, Aluminum Nitride, etc., thermal conductivity of the equivalent layer of the thermal path can be improved (e.g., by a value of 6.7 W/m·K, which is improved by 22%, temperature is decreased, such as by 7.8% for a single DRAM, 9% for a double DRAM, and 9.9% for a triple DRAM). Embodiments of the present technology can be applied to semiconductor or other electrical devices, such as NAND flash memory, NOR flash memory, central processing unit (CPU), graphics processing unit (GPU), having one or more dielectrics disposed between circuitry layers (e.g., CMOS layers). Various features described below can be allied to increase thermal dissipation from the circuitry layers and across the one or more dielectrics. Additionally or alternatively, embodiments of the present technology can be applied in various device applications, such as 3D DRAM, wafer-on wafer (WoW) 3D NAND memory, heterogeneous devices, etc.

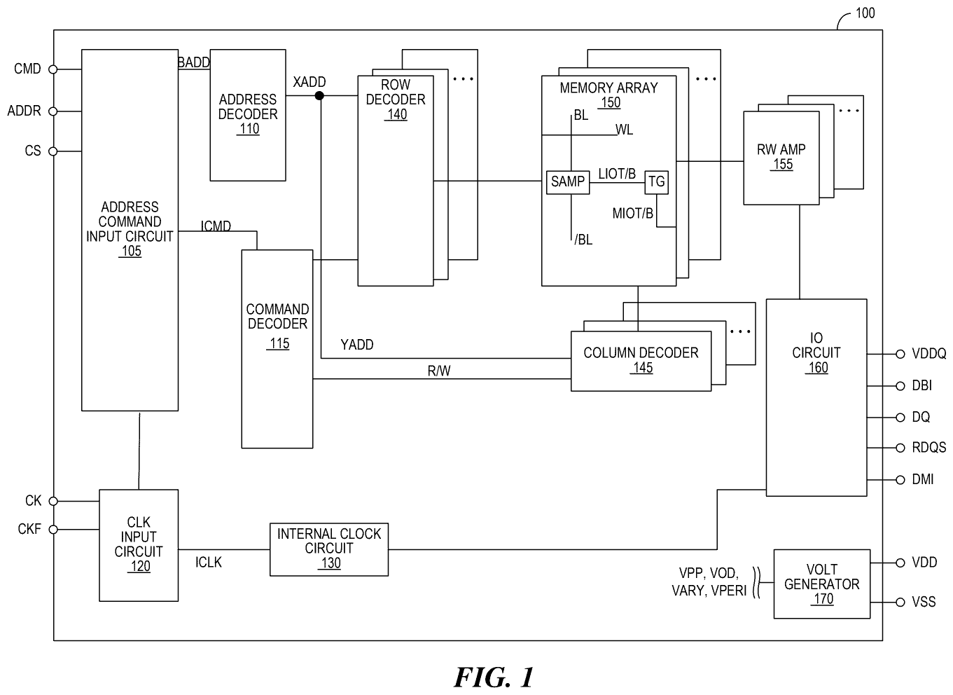

FIG. 1 is a block diagram of an apparatus 100 in accordance with an embodiment of the present technology. For example, the apparatus 100 can include a DRAM (e.g., DDR4 DRAM, DDR5 DRAM, LP DRAM, HBM DRAM, etc.), or a portion thereof that includes one or more dies/chips. In some embodiments, the apparatus 100 can include synchronous DRAM (SDRAM) of DDR type integrated on a single semiconductor chip or on multiple semiconductor chips.

The apparatus 100 may include an array of memory cells, such as memory array 150. The memory array 150 may include a plurality of banks (e.g., banks 0-15), and each bank may include a plurality of word lines (WL), a plurality of bit lines (BL), and a plurality of memory cells arranged at intersections of the word lines and the bit lines. Memory cells can include any one of a number of different memory media types, including capacitive, magnetoresistive, ferroelectric, phase change, or the like. The selection of a word line WL may be performed by a row decoder 140, and the selection of a bit line BL may be performed by a column decoder 145. Sense amplifiers (SAMP) may be provided for corresponding bit lines BL and connected to at least one respective local I/O line pair (LIOT/B), which may in turn be coupled to at least respective one main I/O line pair (MIOT/B), via transfer gates (TG), which can function as switches. The memory array 150 may also include plate lines and corresponding circuitry for managing their operation.

The apparatus 100 may employ a plurality of external terminals that include command and address terminals coupled to a command bus and an address bus to receive command signals (CMD) and address signals (ADDR), respectively. The apparatus 100 may further include a chip select terminal to receive a chip select signal (CS), clock terminals to receive clock signals CK and CKF, data terminals DQ, RDQS, DBI, and DMI, power supply terminals VDD, VSS, and VDDQ.

The command terminals and address terminals may be supplied with an address signal and a bank address signal (not shown in FIG. 1) from outside. The address signal and the bank address signal supplied to the address terminals can be transferred, via a command/address input circuit 105 (e.g., command circuit), to an address decoder 110. The address decoder 110 can receive the address signals and supply a decoded row address signal (XADD) to the row decoder 140, and a decoded column address signal (YADD) to the column decoder 145. The address decoder 110 can also receive the bank address signal and supply the bank address signal to both the row decoder 140 and the column decoder 145.

The command and address terminals may be supplied with command signals (CMD), address signals (ADDR), and chip select signals (CS), from a memory controller. The command signals may represent various memory commands from the memory controller (e.g., including access commands, which can include read commands and write commands). The chip select signal may be used to select the apparatus 100 to respond to commands and addresses provided to the command and address terminals. When an active chip select signal is provided to the apparatus 100, the commands and addresses can be decoded and memory operations can be performed. The command signals may be provided as internal command signals ICMD to a command decoder 115 via the command/address input circuit 105. The command decoder 115 may include circuits to decode the internal command signals ICMD to generate various internal signals and commands for performing memory operations, for example, a row command signal to select a word line and a column command signal to select a bit line. The command decoder 115 may further include one or more registers for tracking various counts or values (e.g., counts of refresh commands received by the apparatus 100 or self-refresh operations (e.g., a self-refresh entry/exit sequence) performed by the apparatus 100).

Read data can be read from memory cells in the memory array 150 designated by row address (e.g., address provided with an active command) and column address (e.g., address provided with the read). The read command may be received by the command decoder 115, which can provide internal commands to input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the apparatus 100, for example, in a mode register (not shown in FIG. 1). The read latency information RL can be defined in terms of clock pulses of the CK clock signal. For example, the read latency information RL can be a number of clock pulses of the CK signal after the read command is received by the apparatus 100 when the associated read data is provided.

Write data can be supplied to the data terminals DQ, DBI, and DMI. The write command may be received by the command decoder 115, which can provide internal commands to the input/output circuit 160 so that the write data can be received by data receivers in the input/output circuit 160 and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the apparatus 100, for example, in the mode register (not shown in FIG. 1). The write latency WL information can be defined in terms of clock pulses of the CK clock signal. For example, the write latency information WL can be a number of clock pulses of the CK signal after the write command is received by the apparatus 100 when the associated write data is received.

The power supply terminals may be supplied with power supply potentials VDD and VSS. These power supply potentials VDD and VSS can be supplied to an internal voltage generator circuit 170. The internal voltage generator circuit 170 can generate various internal potentials VPP, VOD, VARY, VPERI, and the like based on the power supply potentials VDD and VSS. The internal potential VPP can be used in the row decoder 140, the internal potentials VOD and VARY can be used in the sense amplifiers included in the memory array 150, and the internal potential VPERI can be used in many other circuit blocks.

The power supply terminal may also be supplied with power supply potential VDDQ. The power supply potential VDDQ can be supplied to the input/output circuit 160 together with the power supply potential VSS. The power supply potential VDDQ can be the same potential as the power supply potential VDD in an embodiment of the present technology. The power supply potential VDDQ can be a different potential from the power supply potential VDD in another embodiment of the present technology. However, the dedicated power supply potential VDDQ can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK and CKF can be supplied to a clock input circuit 120 (e.g., external clock circuit). The CK and CKF signals can be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 120 can receive the external clock signals. For example, when enabled by a clock/enable signal from the command decoder 115, an input buffer can receive the clock/enable signals. The clock input circuit 120 can receive the external clock signals to generate internal clock signals ICK. The internal clock signals ICK can be supplied to an internal clock circuit 130. The internal clock circuit 130 can provide various phase and frequency controlled internal clock signals based on the received internal clock signals ICK and a clock enable (not shown in FIG. 1) from the command/address input circuit 105. For example, the internal clock circuit 130 can include a clock path (not shown in FIG. 1) that receives the internal clock signal ICK and provides various clock signals to the command decoder 115. The internal clock circuit 130 can further provide input/output (IO) clock signals. The 10 clock signals can be supplied to the input/output circuit 160 and can be used as a timing signal for determining an output timing of read data and the input timing of write data.

The apparatus 100 can be connected to any one of a number of electronic devices capable of utilizing memory for the temporary or persistent storage of information, or a component thereof. For example, a host device of apparatus 100 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to apparatus 100, although in other embodiments, the host device may be indirectly connected to memory device (e.g., over a networked connection or through intermediary devices).

Thermally conductive material can be added at one or more locations within the structure of apparatus 100. The thermally conductive material can provide a thermal path configured to transfer thermal energy out of apparatus 100. For example, thermally conductive material can be located at the same layer as and adjacent to memory array 150.

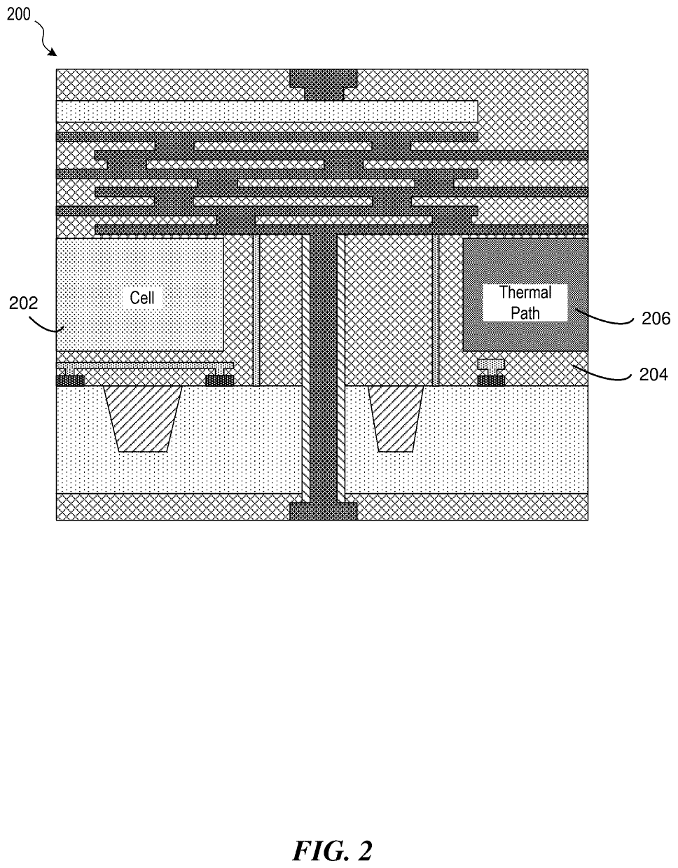

FIG. 2 illustrates a cross-sectional view of the apparatus (e.g., the apparatus 100 of FIG. 1 or a portion thereof) having a thermal path 206, in accordance with one or more embodiments of the present technology. The thermal path 206 can be formed adjacent to a cell structure 202 and embedded in a base dielectric layer 204. In some embodiments, the thermal path 206 is located in a non-cell portion of the memory array (e.g., memory array 150 of FIG. 1). In some embodiments, the thermal path 206 can be disposed between a metal layer and a circuit/CMOS layer. For example, thermal path can be disposed within a frontend of line (FEOL) layer. The thermal path 206 can include thermal conductive, electrically non-conductive material such as Aluminum Oxide, Aluminum Nitride, etc. which do not interfere with other circuitry. The thermal path 206 can provide a path to transfer thermal energy out of the base dielectric layer 204 and the memory device structure 200. For example, the thermal path 206 can be located above CMOS circuitry and provide a path for the thermal energy upward from the CMOS circuitry. Moreover, the thermal path 206 can provide a path for removing thermal energy from the cell structure 202. In some embodiments, the thermal path can be a contiguous material 206. In some other embodiments, the thermal path can be formed to provide maximum thermal transfer in an intended direction.

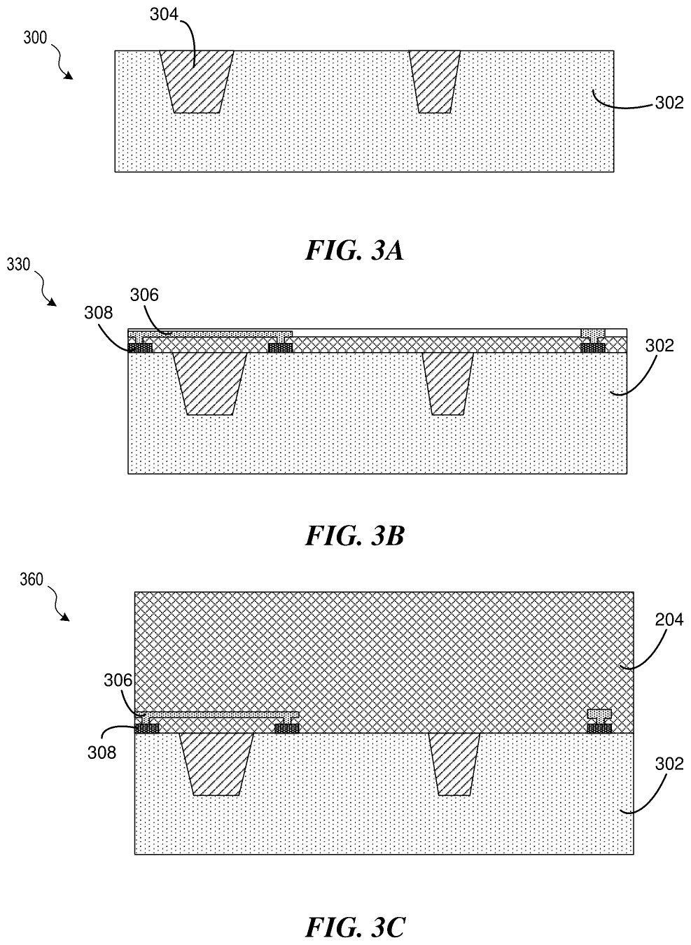

FIGS. 3A-6B can illustrate various stages or structures that are formed during a manufacturing process for the apparatus 100 of FIG. 1. FIG. 3A illustrates a cross-sectional view of the formation an isolation layer in a memory device structure 300, in accordance with one or more embodiments of the present technology. The isolation layer can include one or more trenches 304 formed on a substrate 302 (e.g., silicon wafer).

FIG. 3B illustrates a cross-sectional view of the formation of CMOS 308, local interconnect 306, and wiring (not shown) in a memory device structure 330, in accordance with one or more embodiments of the present technology. The CMOS 308, local interconnect 306, and wiring can be formed about or across the one or more trenches 304. The various circuit components can be formed by depositing or forming components on the isolation layer.

FIG. 3C illustrates a cross-sectional view of the formation of a base dielectric layer (e.g., the base dielectric layer 204) of a memory device structure 360, in accordance with one or more embodiments of the present technology. The base dielectric layer 204 is formed on the substrate 302 (e.g., on the isolation layer). The base dielectric layer 204 can be formed over and/or encompassing the CMOS 308, local interconnect 306, and wiring (not shown). The base dielectric layer 204 can include electrically insulative material, such as Silicon Oxide material.

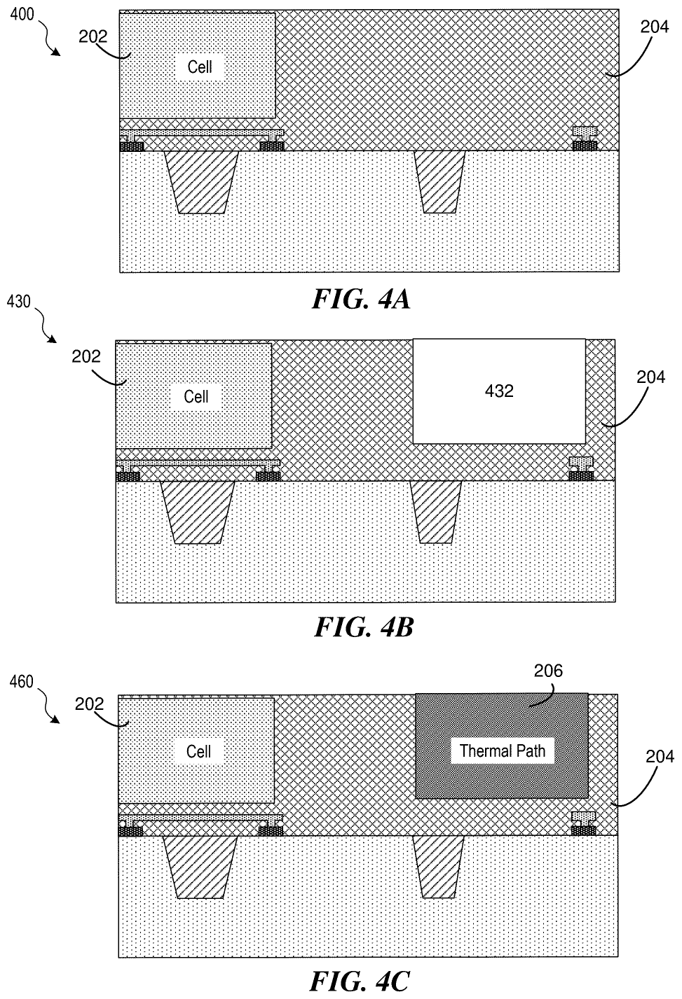

FIG. 4A illustrates a cross-sectional view of the formation of a cell structure (e.g., the cell structure 202) in the base dielectric layer 204 in a memory device structure 400, in accordance with one or more embodiments of the present technology. The cell structure 202 can be formed in the base dielectric layer 204. For example, the cell structure 202 can be formed based on removing portions of the base dielectric layer 204 to form a cavity or a base shape, depositing metallic material, dopants, and/or circuit components within the cavity, masking, patterning, or a combination thereof. In some embodiments, such as for DRAMs, the cell structure 202 can include capacitor-based circuitry.

FIG. 4B illustrates a cross-sectional view of the formation of an isolated area 432 for a thermal path in a memory device structure 430, in accordance with one or more embodiments of the present technology. The isolated area 432 can be formed in the base dielectric layer 204, such as by removing or etching a targeted portion of the based dielectric layer 204. Effectively, the isolated area 432 can correspond to a cavity or a depression what is later occupied by the thermal path 206 of FIG. 2. The isolated area 432 can be separated along a lateral direction from the cell structure 202 of FIG. 4A. In some embodiments (not shown), the isolated area 432 can be formed over a through silicon via (TSV) or a thermal via. The isolated area 432 of thermal path can be isolated in the base dielectric layer 204 from areas designated for other circuitry components, such as the contact, vias, and/or TSVs.

FIG. 4C illustrates a cross-sectional view of the formation of a thermal path (e.g., the thermal path 206) in a memory device structure 460, in accordance with one or more embodiments of the present technology. The thermal path 206 can be formed by filling or depositing thermally conductive material in the base dielectric layer 204 in the isolated area 432 of FIG. 4B. The thermal path 206 can be formed in the base dielectric layer 204 using highly thermal conductive and/or electrically non-conductive material, such as Aluminum Oxide, Aluminum Nitride, etc. In some embodiments, the thermal path 206 can be formed by a process of spin coating, a deposition process, a polishing process, or a combination thereof.

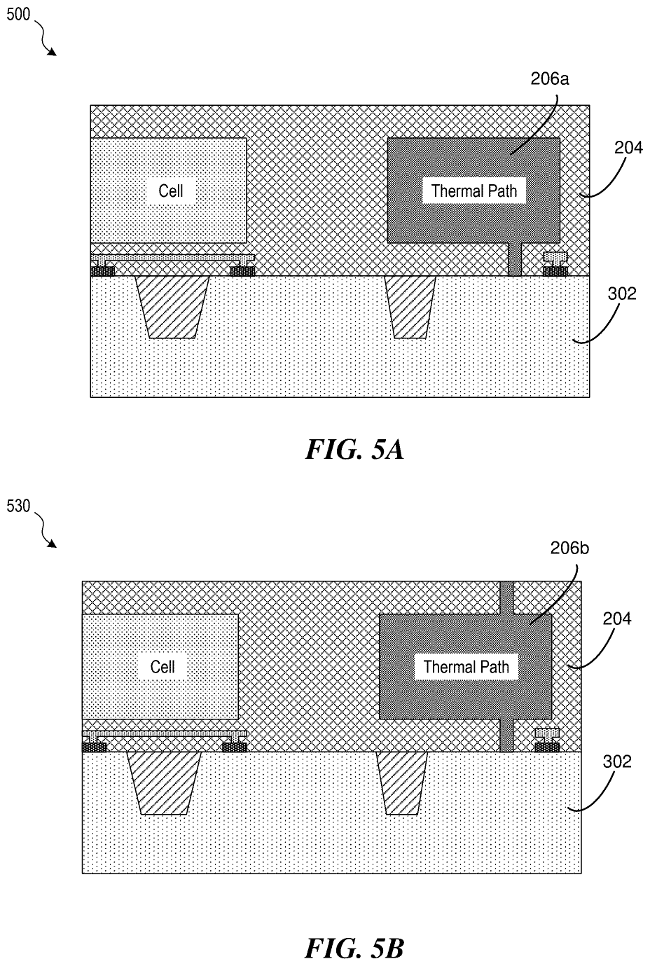

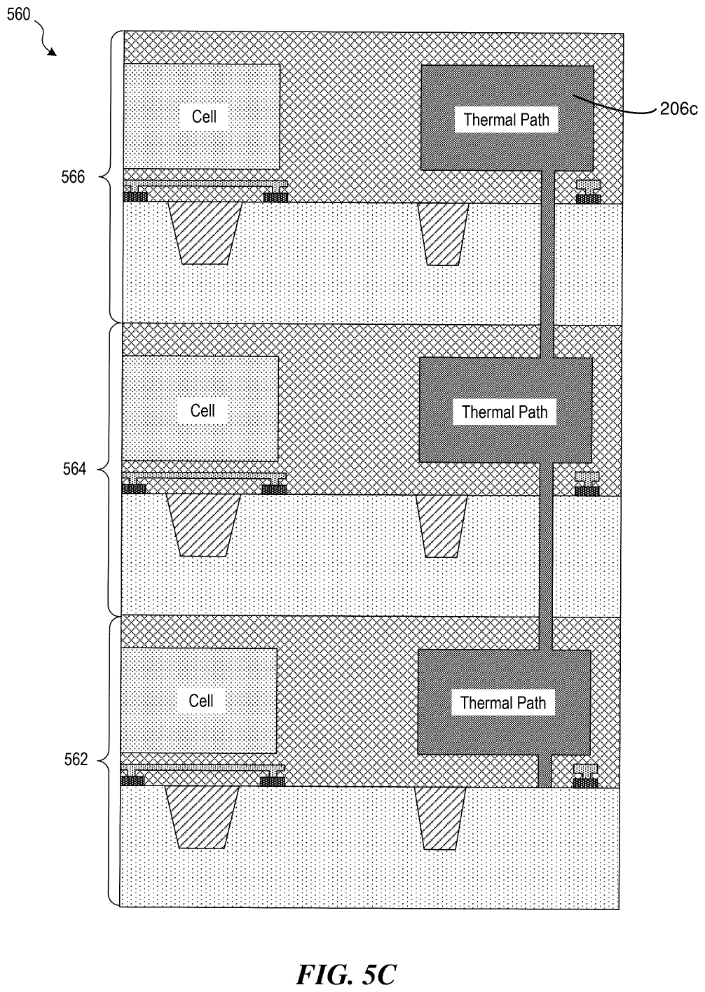

FIGS. 5A and 5B illustrate different embodiments for the thermal path 206. FIG. 5A illustrates a cross-sectional view of the formation a thermal path 206a from the base dielectric layer 204 and connected to the substrate 302 in a memory device structure 500, in accordance with one or more embodiments of the present technology. The thermal path 206 can extend from the base dielectric layer 204 up to and/or into the isolation layer. For example, the isolated area 432 of FIG. 4B can have an additional extension that exposes a portion of the substrate 302. The additional extension in the cavity can be occupied by the thermal conductive and/or electrically non-conductive material, thereby forming the thermal path 206a having an extension extending toward and/or contacting the substrate 302. In some embodiments, the base dielectric layer 204 can be formed or redeposited over the thermal path 206, thereby encompassing a top portion of the thermal path 206a.

FIG. 5B illustrates a cross-sectional view of the formation of a thermal path 206b through the base dielectric layer 204 and connected to the substrate 302 in a memory device structure 530, in accordance with one or more embodiments of the present technology. Thermal path 206 can extend through a portion or the entirety of the base dielectric layer 204. For example, the isolated area 432 of FIG. 4B can have an additional extension that exposes a portion of the substrate 302. The additional extension in the cavity can be occupied by the thermal conductive and/or electrically non-conductive material, thereby forming the thermal path 206b having an extension extending toward and/or contacting the substrate 302. In some embodiments, the base dielectric layer 204 can be formed or redeposited over the thermal path 206b with a cavity that is further filled by the thermal conductive and/or electrically non-conductive material. As a result the thermal path 206b can have a second extension extending upward and through the base dielectric layer 204.

FIG. 5C illustrates a cross-sectional view of a stacked thermal path 206c in a memory device 560, in accordance with one or more embodiments of the present technology. As an illustrative example, the thermal path 206c can connect continuously through memory device structures 562, 564, and 566. For example, the memory device 560 can be formed by wafers or die having the thermal path 206a and/or 206b stacked (e.g., wafer bonded or stacked die) on top of each other. The stacked wafers or stacked die can further include through silicon vias or corresponding thermal extensions that directly contact the vertical extension portions of the thermal paths 206a and/or 206b. Accordingly, the resulting thermal path 206c can have the thermal paths 206a and/or 206b aligned and directly connected to each other across multiple layers. During operation, the thermal path 206 can provide a path for the thermal energy to flow between the memory device structure 566, 564, and 562.

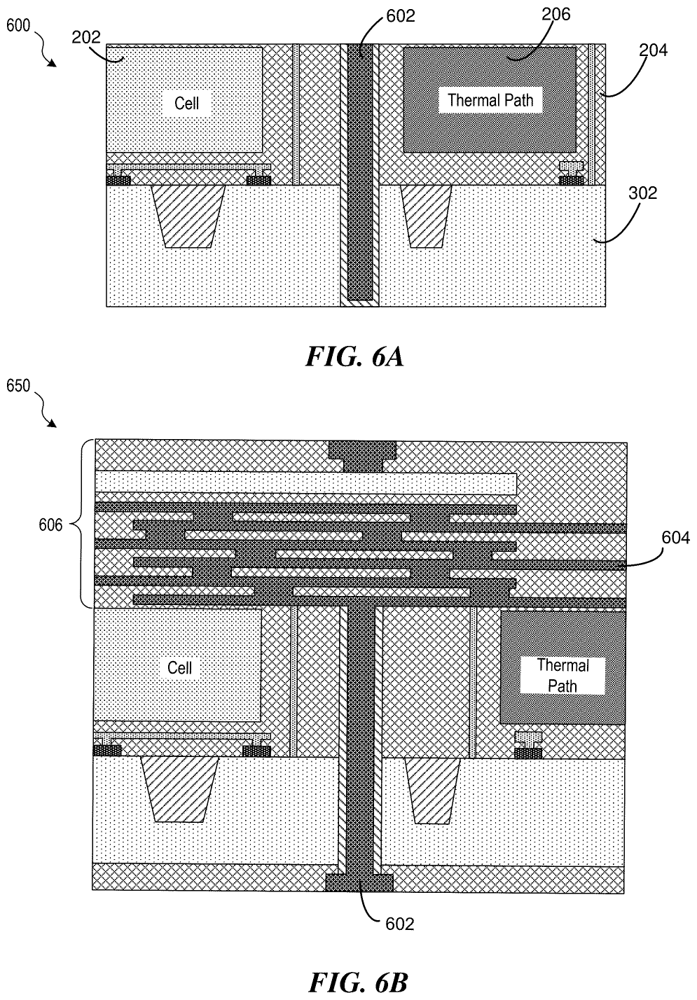

FIG. 6A illustrates a cross-sectional view of the formation of a via 602 of a memory device structure 600, in accordance with one or more embodiments of the present technology. The via 602 can be formed on or after the memory device structure 460 of FIG. 4C, the memory device structure 500 of FIG. 5A, or the memory device structure 530 of FIG. 5B. The via 602, such as a TSV or contact, can extend through the substrate 302 and the base dielectric layer 204. As an illustrative example, the via 602 can separate the thermal path 206 from the cell structure 202 in the base dielectric layer 204. The via 602 can be formed by removing or etching to form a cavity that extends through the base dielectric layer 204 and/or the substrate 302. The via cavity can be filled using barrier material, seed metallic material, main metallic material (e.g., copper), or a combination thereof.

FIG. 6B illustrates a cross-sectional view of the formation of a redistribution layer 604 in an EOL layer 606 of a memory device structure 650, in accordance with one or more embodiments of the present technology. The redistribution layer 604 can include lateral electrical connection, such as traces, local vias, or a combination thereof. The redistribution layer 604 can connect to the via 602, the cell structure 202, the CMOS 308, the local interconnect 306, or a combination thereof. Accordingly, the redistribution layer 604

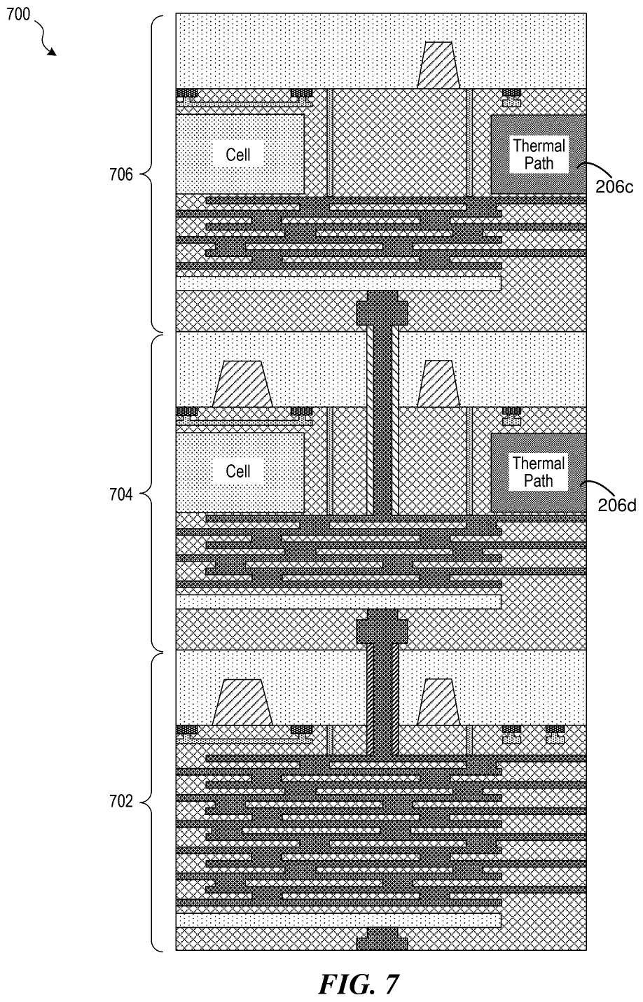

FIG. 7 illustrates a cross-sectional view of thermal paths 206c and 206d on memory devices 704 and 706 connected to a logic circuit 702 of an apparatus 700 (e.g., apparatus 100 of FIG. 1), in accordance with one or more embodiments of the present technology. For illustrative purposes, FIG. 7 can depict portions of directly bonded semiconductor wafers or a corresponding stacked device having memory or data storage circuitry (e.g., memory cells, such as for DRAMs). For example, the illustrated portions of memory devices 704 and 706 can correspond to the memory array 150 of FIG. 1. The logic circuit 702 can correspond to other circuitry illustrated in FIG. 1, such as the address command input circuit 105 of FIG. 1, the I/O circuit 160 of FIG. 1, and/or the like.

The memory devices 704 and 706 can include the thermal paths, such as the thermal path 206 of FIG. 2, 206a of FIG. 5A, and/or 206B of FIG. 5B, for managing thermal energy of the apparatus 700. The thermal paths 206c and 206d can provide a thermally conductive route for the flow of thermal energy from the logic circuit 702 to memory device 704 and exit at memory device 706. Once the manufacturing process (illustrated in FIGS. 3A-6B) for memory devices 704 and 706 is complete, the memory devices 704 and 706 can be flipped (via, e.g., a carrier wafer) and mounted over logic circuit 702, resulting in apparatus 700. This way, the active side of the memory devices 704 and 706 can face down and closer to the logic circuit 702 at the bottom of apparatus 700.

In some embodiments, the thermal paths 206a and 206b are connected (as illustrated in FIG. 5C) to provide a directly linked path (e.g., a thermal pillar or a path to a thermal pillar that includes thermally conductive and/or electrically insulative materials described above) for the heat to dissipate out of the apparatus 700. For illustrative purposes, the thermal path has a quadrilateral cross-sectional shape. However, it is understood that the various embodiments described herein can be implemented in other configurations, such as for any dimensions and shapes of a thermal path in a memory device structure.

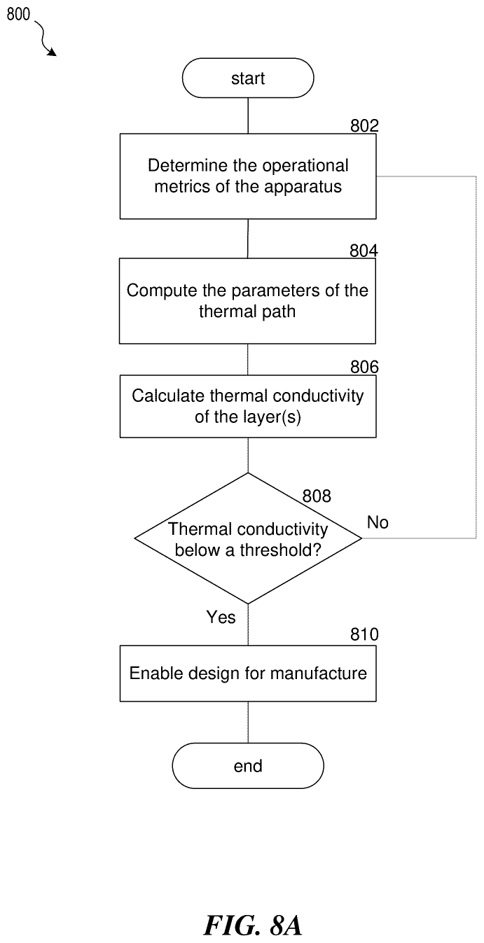

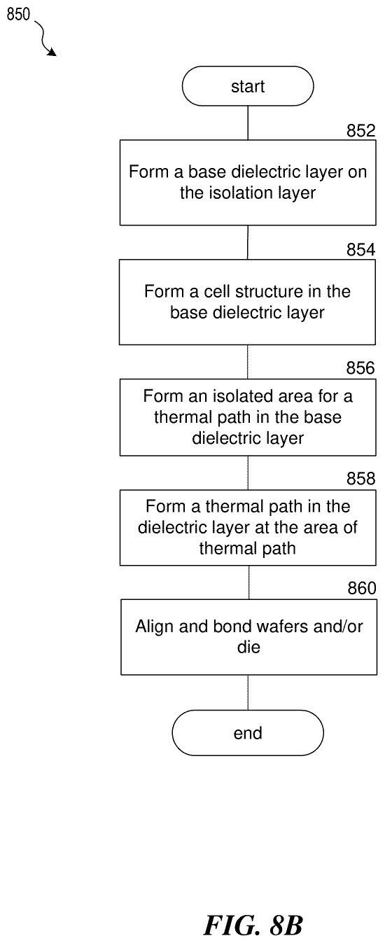

FIG. 8A is a flow diagram illustrating an example method 800 of designing a thermal path for a memory device structure, in accordance with one or more embodiments of the present technology. The method 800 can determine the placement (e.g., size, shape, location, or the like) of a thermal path (e.g., the thermal path 206 of FIGS. 2-7) in a memory device structure, as described above.

At block 802, method 800 can include determining the operational metrics of an apparatus (e.g., apparatus 100 of FIG. 1 and/or apparatus 700 of FIG. 7). The operational metrics can include bandwidth requirements, circuit capacity, operating speeds, heat displacement, footprint, or any devices design preferences or standards. In some embodiments, the operational metrics can be determined according to a circuit diagram or a requirement regarding the same provided by another party or entity, such as a circuit designer or a customer.

At block 804, method 800 can include computing the parameters (e.g., position, size, shape, length, width, depth, and/or number) of the thermal path based on the operational metrics of the apparatus. The thermal path can be placed in the memory device structure to provide a path for the thermal energy to dissipate out of the memory structure. The method can include determining where in the memory device structure to place the thermal path. For example, the thermal path can be placed in the base dielectric layer, the isolation layer, or across multiple layers in the memory device structure.

Method 800 can include computing the parameters (e.g., location and/or shape) of the thermal path based on cell structures, vias, sockets, receptacles, solder locations, holes, connectors, or any feature in the memory device structure. For example, the manufacturing system can generate a layout for the thermal path that avoids placing the thermal path at, under, overlapping, and/or within a threshold distance from vias or cell structures in the memory device structure.

A machine learning or artificial intelligence (ML/AI) module may be configured to analyze operational metrics of a memory device and compute the parameters of a thermal path(s) to add to the memory device structure to remove thermal energy. The ML/AI learning module may be configured to analyze the operational metrics and compute the parameters of the thermal path based on at least one ML/AI model trained on at least one dataset reflecting previous user determined parameters of thermal paths based on operational metrics. The ML/AI algorithm (and model) may be stored locally at databases and/or externally at databases (e.g., cloud databases and/or cloud servers). Client devices (e.g., personal computers, smart phones, tablets, etc.) may be equipped to access these ML/AI algorithms and intelligently compute parameters of thermal paths in the memory device structure based on at least one ML/AI model that is trained on historical thermal path parameters. For example, thermal path parameter history may be collected to train a ML/AI model to automatically determine the position, size, shape, length, width, depth, and/or number of thermal paths based on the operating parameters of the memory device.

As described herein, a ML/AI model may refer to a predictive or statistical utility or program that may be used to determine a probability distribution over one or more character sequences, classes, objects, result sets or events, and/or to predict a response value from one or more predictors. A model may be based on, or incorporate, one or more rule sets, machine learning, a neural network, or the like. The ML/AI models may process historical parameters of thermal paths in memory devices and other data stores (e.g., semiconductor standards, etc.) to analyze the memory device structure and design the thermal path location and size in the memory device structure. Based on an aggregation of data from a memory device design database, external/internal portals, and other user data stores, at least one ML/AI model may be trained and subsequently deployed to automatically design memory devices with a thermal path(s) inserted in the one or more layers of the memory device structure.

At block 806, method 800 can include calculating (using, e.g., a computing system) the thermal conductivity of the layer(s) in the memory device structure. The calculation can be based on simulation testing on the layer(s) with the added thermal path to calculate the thermal conductivity for the memory device. For example, by adding the thermal path to the layer(s) of the memory device structure, the thermal conductivity can be improved and the operational temperature decreased. The simulation results can show the predicted thermal conductivity improvement or the changes in the device temperature by adding the thermal path to the layer(s) of the memory device structure.

At decision block 808, method 800 can include determining whether the thermal conductivity for the layer(s) is below a threshold (e.g., 200 W/m·K). If the estimated thermal conductivity for the layer(s) is not below a predetermined acceptance threshold, method 800 can include adjusting the parameters of the thermal path inserted in the layer(s) of the memory device structure as illustrated by the feedback loop to block 804. If the thermal conductivity value for the layer(s) is below the threshold, at block 810, method 800 enables the design for manufacture.

Based on the approval, the device design can be utilized to manufacture the memory device with the thermal path in one or more layers of the memory device structure. For example, the device design can be provided to the memory device manufacturer. When manufacturing the memory device according to the approved design, the thermal path or material can be arranged within the one or more layers of the memory device structure according to the design.

FIG. 8B is a flow diagram illustrating an example method 850 of manufacturing a thermal path in one or more layers of a memory device structure, in accordance with one or more embodiments of the present technology. Method 850 can include adding a thermally conductive material during the FEOL layer manufacturing phase. The FEOL layer can include the isolation layer that interconnects with a CMOS formation (e.g., CMOS 308 of FIGS. 3-7) and local wiring.

At block 852, method 850 can include forming a base dielectric layer (e.g., base dielectric layer 204 of FIGS. 2-7) on the isolation layer. The base dielectric layer can be formed to add the thermally conductive material during the FEOL manufacturing phase. At block 854, method 850 can include forming a cell structure (e.g., cell structure 202 of FIGS. 2-7) in the base dielectric layer.

At block 856, method 850 can include forming, adjacent to the cell structure, an isolated area (e.g., isolated area 432 of FIG. 4B) for a thermal path in the base dielectric layer. The area of thermal path can be electrically isolated using the base dielectric layer from the area of peripheral circuitry and the areas of contact, vias, and/or TSVs, such as by preserving or forming vertical portions or walls surrounding the thermal path portions.

At block 858, method 850 can include forming a thermal path (e.g., thermal path 206 of FIGS. 2-7) in the dielectric layer at the area of thermal path by adding thermally conductive, electrically non-conductive material such as Aluminum Oxide, Aluminum Nitride, etc. The thermal path can be formed by a process of spin coating, which contains the thermally conductive material as a filler in the base dielectric layer. In some embodiments, the thermal path is formed by a combination of processes, such as physical vapor deposition (PVD), molybdenum (MO), or cut metal dielectric (CMD), to form a thermally conductive layer as a functional film and removed by a polishing process. The manufacturing process can be completed by implementing a back end-of-line (BEOL) process to form the wiring of the memory device.

At block 860, method 850 can include aligning and bonding wafers and/or die. For example, the method 850 can include manufacturing one or more wafers/die, such as a wafer including the logic circuit 702 of FIG. 7, one or more wafers or die including the memory devices 704/706 of FIG. 7, or a combination thereof using the processes described above for blocks 852-858. The wafers or die can be aligned, such as using markers. In aligning the wafers or die, the thermal paths 206 in the wafers or die can be vertically stacked or aligned along a vertical line.

The aligned wafers or die can be attached, such as via direct wafer-to-wafer bonding. For example, the wafers or die can be arranged over each other or stacked such that copper pads on top and bottom pads directly contact each other. The contacting copper pads can be directly bonded to each other (e.g., without adhesive or solder), such as using diffusion bonding, ultrasonic welding, or other similar direct bonding mechanisms.

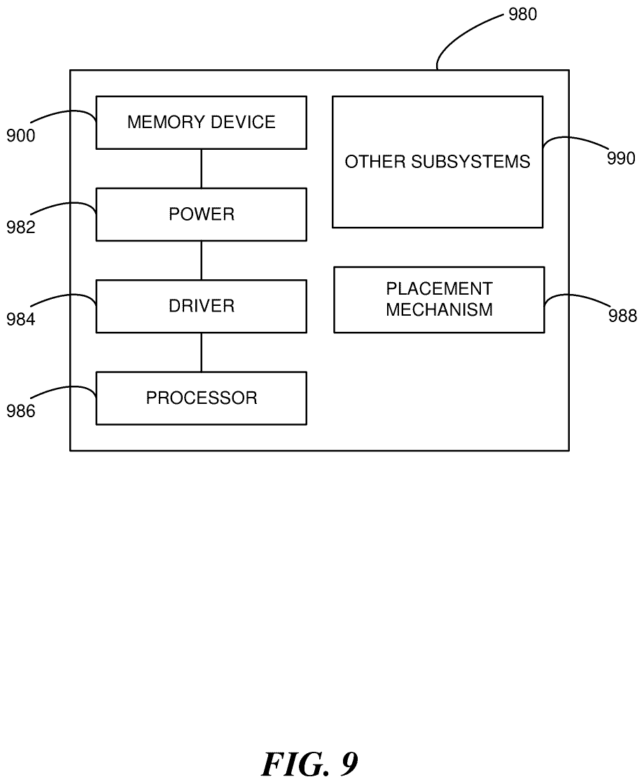

FIG. 9 is a schematic view of a system that includes an apparatus in accordance with embodiments of the present technology. Any one of the foregoing apparatuses (e.g., memory devices) associated with the memory devices described above with reference to FIGS. 1-8B can be incorporated into or implemented in memory (e.g., a memory device 900) or any of a myriad of larger and/or more complex systems, a representative example of which is system 980 shown schematically in FIG. 9. The system 980 can include the memory device 900, a power source 982, a driver 984, a processor 986, a placement mechanism 988, and/or other subsystems or components 990. The placement mechanism 988 can use ML/AI models to determine the position, size, shape, length, width, depth, and/or number of thermal paths to add to the memory device structure based on the operational metrics of the memory device (as described in FIGS. 8A and 8B).

The memory device 900 can include features generally similar to those of the apparatus described above with reference to FIGS. 1-8B and can therefore include various features for performing a direct read request from a host device. The resulting system 980 can perform any of a wide variety of functions, such as memory storage, data processing, and/or other suitable functions. Accordingly, representative systems 980 can include, without limitation, hand-held devices (e.g., mobile phones, tablets, digital readers, and digital audio players), computers, vehicles, appliances and other products. Components of the system 980 may be housed in a single unit or distributed over multiple, interconnected units (e.g., through a communications network). The components of the system 980 can also include remote devices and any of a wide variety of computer readable media.

From the foregoing, it will be appreciated that specific embodiments of the technology have been described herein for purposes of illustration, but that various modifications may be made without deviating from the technology. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the present technology and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structures includes information arranged as bits, words or code-words, blocks, files, input data, system generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-9.

I/We claim:

1. An apparatus comprising:
a semiconductor substrate;
a memory cell over the semiconductor substrate;
a thermal path over the semiconductor substrate and separated from the memory cell along a lateral direction, the thermal path including thermally conductive and electrically insulative material; and
a dielectric material encompassing at least peripheral portions of the memory cell and the thermal path and forming a layer over the semiconductor substrate.

2. The apparatus of claim 1,
wherein the thermal path includes material that is more thermally conductive than the dielectric material, and
wherein the thermal path is configured to transfer thermal energy out of or through the apparatus.

3. The apparatus of claim 1, wherein the thermal path is electrically isolated, using the semiconductor substrate, from the memory cell.

4. The apparatus of claim 1, wherein the thermally conductive and electrically insulative material is Aluminum Oxide or Aluminum Nitride.

5. The apparatus of claim 1, wherein the thermal path includes a top portion, a bottom portion, or both that is exposed through the semiconductor substrate.

6. A memory device comprising:
a semiconductor substrate portion;
a dielectric layer over the semiconductor substrate portion;
at least one cell structure disposed in the dielectric layer and configured to store electrical charges representative of stored data; and
a thermal path located adjacent to the at least one cell structure and at least partially embedded in the dielectric layer, the thermal path including thermally conductive and electrically insulative material.

7. The memory device of claim 6,
wherein the thermal path includes material that is more thermally conductive than dielectric material of the dielectric layer, and
wherein the thermal path is configured to transfer thermal energy out of or through the memory device.

8. The memory device of claim 6, wherein the thermal path is electrically isolated, using the dielectric layer, from the at least one cell structure.

9. The memory device of claim 6, wherein the thermally conductive and electrically insulative material is Aluminum Oxide or Aluminum Nitride.

10. The memory device of claim 6, further comprising:
active circuitry below the at least one cell structure and disposed on or above the semiconductor substrate portion; and
a through silicon via (TSV) extending along a vertical direction and through the dielectric layer, the semiconductor substrate portion, or both.

11. The memory device of claim 6, further comprising:
a logic device wafer including logic circuitry configured to facilitate storage, access, and maintenance of the data stored in the memory device,
wherein the semiconductor substrate portion, the dielectric layer, the at least one cell structure, and the thermal path comprise a semiconductor storage device configured to store data, the semiconductor storage device is wafer bonded to and over the logic device,
wherein the thermal path is configured to allow thermal energy generated by the logic device to travel upward and through the semiconductor storage device.

12. The memory device of claim 11, wherein the semiconductor storage device is a first storage device having a first thermal path and directly attached to the logic device, the memory device further comprising:
a second storage device having a second thermal path and wafer bonded directly to and over the first storage device, wherein the first and second thermal paths are aligned along a vertical line.

13. The memory device of claim 6, wherein the memory device comprises a dynamic random-access memory (DRAM).

14. A method comprising:
providing a semiconductor substrate;
forming at least one cell structure over the semiconductor substrate, wherein the at least one cell structure is configured to store data;
forming a dielectric layer over the semiconductor substrate and encompassing the at least one cell structure;
forming, adjacent to the at least one cell structure, at least one isolated area based on removing a portion of the dielectric layer; and
forming a thermal path in the dielectric layer at the at least one isolated area by adding thermally conductive and electrically insulative material in the at least one isolated area.

15. The method of claim 14, wherein forming the thermal path includes:
spin coating to deposit the thermally conductive and electrically insulative material in the at least one isolated area of the dielectric layer.

16. The method of claim 14, wherein forming the thermal path includes:
a physical vapor deposition (PVD) process, a molybdenum (MO) process, a cut metal dielectric (CMD) process, or a combination thereof to deposit the thermally conductive and electrically insulative material.

17. The method of claim 14, wherein the thermally conductive and electrically insulative material is added during a front-end-of-line (FEOL) layer manufacturing phase.

18. The method of claim 14, wherein the thermally conductive and electrically insulative material is more thermally conductive than dielectric material of the dielectric layer, and wherein the thermally conductive and electrically insulative material provides the thermal path to transfer thermal energy out of or through the dielectric layer.

19. The method of claim 14, further comprising:
forming or attaching active circuitry on the semiconductor substrate, wherein the at least one cell structure is formed over the active circuitry; and
forming a thermal via or through silicon via (TSV) that extends through the dielectric layer and extends into the semiconductor substrate, wherein the thermal via or the TSV is located between the at least one cell structure and the thermal path,
wherein the thermal path is physically separated and electrically isolated, using the dielectric layer, from the thermal via or the TSV and the active circuitry.

20. The method of claim 14, wherein forming the thermal path includes depositing Aluminum Oxide or Aluminum Nitride in the at least one isolated area.
